(19) United States
(12) Patent Application Publication
(10) Pub. No.: US 2026/0041001 A1
(43) Pub. Date: Feb. 5, 2026

(54) SEMICONDUCTOR PACKAGE

(71) Applicant: Samsung Electronics Co., Ltd., Suwon-si (KR)

(72) Inventor: Eunsu Lee, Suwon-si (KR)

(21) Appl. No.: 19/059,866

(22) Filed: Feb. 21, 2025

(30) Foreign Application Priority Data
Aug. 2, 2024 (KR) 10-2024-0103356

(51) Int. Cl. H01L 23/00; H01L 21/56; H01L 23/31; H01L 23/538; H01L 25/07; H10B 80/00

(52) U.S. Cl. CPC H01L 24/24; H01L 24/19; H01L 24/32; H01L 24/73; H01L 25/072; H01L 21/56; H01L 23/3128; H01L 23/538; H01L 2224/19; H01L 2224/24137; H01L 2224/244; H01L 2224/32225; H01L 2224/73267; H10B 80/00

(57) ABSTRACT

A semiconductor package includes a first substrate including a first interconnection structure, a first semiconductor chip, a second semiconductor chip, a second substrate, a molding layer between the first substrate and the second substrate, a plurality of conductive bumps that electrically connect the first interconnection structure to a first chip pad on a second surface of the first semiconductor chip that is opposite to the first surface of the first semiconductor chip, and a plurality of conductive wires that electrically connect the first interconnection structure to a second chip pad on a second surface of the second semiconductor chip that is opposite to the first surface of the second semiconductor chip.

### CROSS-REFERENCE TO RELATED APPLICATION(S)

This application claims the benefit of Korean Patent Application No. 10-2024-0103356, filed on Aug. 2, 2024, in the Korean Intellectual Property Office, the disclosure of which is incorporated herein by reference.

### TECHNICAL FIELD

Example embodiments relate to a semiconductor package.

### BACKGROUND

A semiconductor package is an integrated circuit chip implemented in a form suitable for use in electronic products, and in order to miniaturize and increase the capacity of semiconductor packages, a package on package structure is being utilized.

In the semiconductor package, semiconductor chips are mounted on a printed circuit board (PCB) and the semiconductor chips and the PCB are electrically connected using bonding wires or bumps.

With respect to the semiconductor package, a structure is desired by which damage to the bonding wire during the manufacturing process can be prevented, and the space required for wiring can be reduced.

### SUMMARY

An aspect provides a semiconductor package by which wires connecting semiconductor chips and a substrate are not damaged during the semiconductor package manufacturing process.

Another aspect also provides a semiconductor package by which the overall size is reduced and the warpage phenomenon due to thermal stress difference is reduced.

The technical tasks to be achieved by the present example embodiments are not limited to the technical tasks described above, and other technical tasks may be inferred from the following example embodiments by those skilled in the art.

According to an aspect, there is provided a semiconductor package including a first substrate including a first interconnection structure, a first semiconductor chip on the first substrate, a second semiconductor chip that is on the first substrate and spaced apart from the first semiconductor chip in a first direction that is parallel to an upper surface of the first substrate, a second substrate that is spaced apart from the upper surface of the first substrate in a second direction that is perpendicular to the upper surface of the first substrate, where the second substrate contacts a first surface of the first semiconductor chip and a first surface of the second semiconductor chip, a molding layer between the first substrate and the second substrate, a plurality of conductive bumps that electrically connect the first interconnection structure to a first chip pad on a second surface of the first semiconductor chip that is opposite to the first surface of the first semiconductor chip, and a plurality of conductive wires that electrically connect the first interconnection structure to a second chip pad on a second surface of the second semiconductor chip that is opposite to the first surface of the second semiconductor chip.

According to another aspect, there is provided a method of manufacturing a semiconductor package including attaching a first surface of a first semiconductor chip and a first surface of a second semiconductor chip at different positions on a first surface of an interposer substrate, attaching a connecting member to a second surface of the second semiconductor chip that is opposite to the first surface of the second semiconductor chip, forming a molding layer on the first surface of the interposer substrate to at least partially overlap a second surface of the first semiconductor chip that is opposite to the first surface of the first semiconductor chip and the second surface of the second semiconductor chip, forming a substantially flat molding surface by removing a portion of the molding layer, and providing a base substrate on the substantially flat molding surface.

According to another aspect, there is provided a semiconductor package including a base substrate including a lower surface and an upper surface, an external connection terminal on the lower surface of the base substrate, a logic chip spaced apart from the base substrate in a first direction that is perpendicular to the upper surface of the base substrate, a memory chip spaced apart from the base substrate in the first direction and from the logic chip in a second direction parallel to the upper surface of the base substrate, an interposer substrate on an upper surface of the logic chip and an upper surface of the memory chip, a molding layer between the base substrate and the interposer substrate, a chip pad on a lower surface of the memory chip that is opposite to the upper surface of the memory chip, an upper connection pad that is on the upper surface of the base substrate and faces the chip pad in the first direction, and a connecting member including a first end that is electrically connected to the chip pad and a second end that is electrically connected to the upper connection pad.

Additional aspects of example embodiments will be set forth in part in the description which follows and, in part, will be apparent from the description, or may be learned by practice of the disclosure.

According to example embodiments, it is possible for wires connecting semiconductor chips and a substrate not to be damaged during the semiconductor package manufacturing process.

Further, according to example embodiments, it is possible to reduce the overall size of a semiconductor package, and accordingly, it is possible to reduce the warpage phenomenon caused by thermal stress differences in each layer of the semiconductor package.

However, effects of the present disclosure are not limited to those described above, and may be expanded in various ways without departing from the spirit and scope of the present disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a layout drawing schematically illustrating a semiconductor package according to an example embodiment;

FIG. 2 is a cross-sectional view of a semiconductor package according to one embodiment taken along line I-I′ of FIG. 1;

FIG. 3 is an enlarged view of part A of FIG. 2;

FIG. 4 is a cross-sectional view illustrating a plurality of conductive connectors formed on a second substrate;

FIG. 5 is a cross-sectional view illustrating a first semiconductor chip and a second semiconductor chip attached to a second substrate;

FIG. 6 is a cross-sectional view illustrating a conductive wire connected to a second semiconductor chip;

FIG. 7 is a cross-sectional view illustrating a molding layer formed on a second substrate;

FIG. 8 is a cross-sectional view illustrating a flat molding surface formed by grinding a portion of the molding layer;

FIG. 9 is a cross-sectional view illustrating the first substrate formed on the molding layer;

FIG. 10 is a cross-sectional view illustrating that after a first substrate, a molding layer and a second substrate are mutually bonded and inverted, an external connection terminal is formed on a first substrate lower portion;

FIG. 11 is a cross-sectional view illustrating a third semiconductor chip arranged on a second substrate;

FIG. 12 is a cross-sectional view of a semiconductor package according to another example embodiment taken along line I-I′ of FIG. 1; and

FIG. 13 is a cross-sectional view of a semiconductor package according to another example embodiment taken along line I-I′ of FIG. 1.

### DETAILED DESCRIPTION

Prior to the detailed description of the present disclosure, terms or words used in the specification and claims should not be construed as limited to their common or dictionary meanings. Further, the terms or words should be interpreted with meaning and concept consistent with the technical idea of the present disclosure. The example embodiments described in this specification and the configurations shown in the drawings are only example embodiments of the present disclosure, and do not necessarily represent the entire technical idea of the present disclosure. Accordingly, at the time of filing the present disclosure, there may be various equivalents and modifications that can replace them.

To clarify the present disclosure, the same elements or equivalents are referred to by the same reference numerals throughout the specification. In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. The terms “comprises” “have,” “may have,” “include,” and “may include” as used herein indicate the presence of corresponding features (for example, elements such as numerical values, functions, operations, or parts), and do not preclude the presence of additional features. It will be understood that when an element such as a layer, film, region, or substrate is referred to as being “on” another element, it can be directly on the other element or intervening elements may also be present. In contrast, when an element is referred to as being “directly on” another element, there are no intervening elements present. As used herein, the singular forms “a,” “an” and “the” are intended to include the plural forms as well, unless the context clearly indicates otherwise. The term “exposed” may be used to define a relationship between particular layers or surfaces, but it does not require the layer or surface to be free of other elements or layers thereon in the completed device. Components or layers described with reference to “overlap” in a particular direction may be at least partially obstructed by one another when viewed along a line extending in the particular direction or in a plane perpendicular to the particular direction. The terms “first,” “second,” etc. may be used herein to merely distinguish one component, element, etc., from another.

Further, in the following description, expressions such as an upper side, top, a lower side, bottom, a side, front and a back side are expressed based on the direction shown in the drawing. If the direction of the object changes, it may be expressed differently, it will be understood that the spatially relative terms are intended to encompass different orientations of the device in use or operation in addition to the orientation depicted in the figures. The shapes and sizes of elements in the drawings may be exaggerated for clearer explanation.

Hereinafter, semiconductor packages according to example embodiments will be described with reference to the attached drawings.

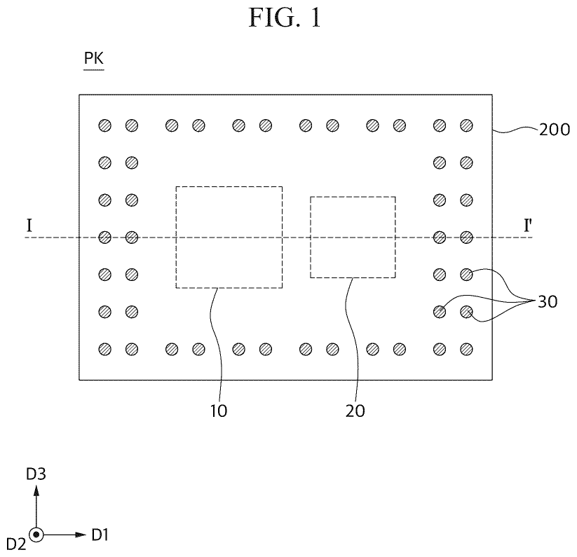

FIG. 1 is a layout drawing of a semiconductor package PK according to one example embodiment.

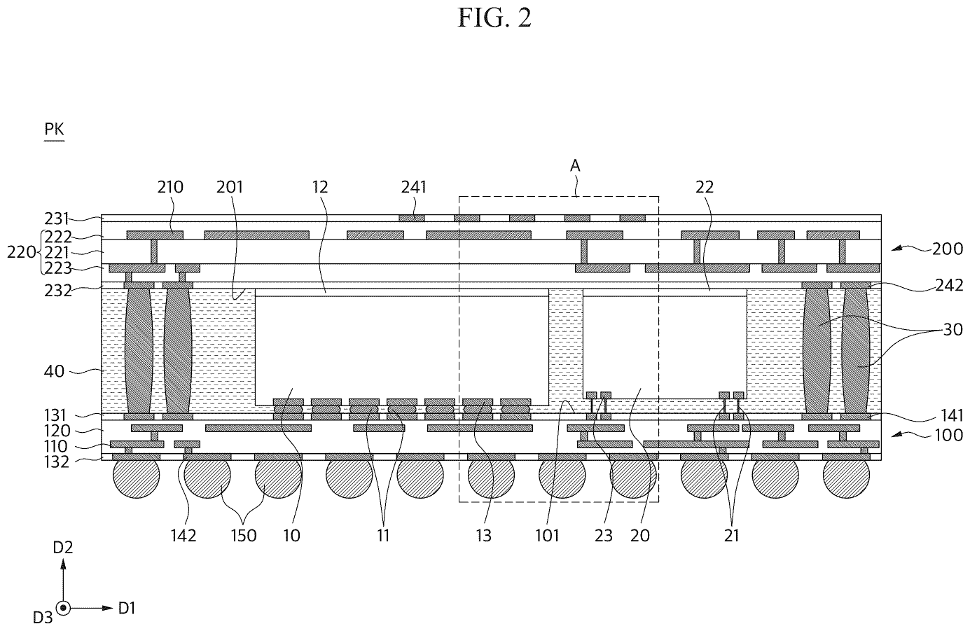

FIG. 2 is a cross-sectional view of the semiconductor package PK according to one example embodiment.

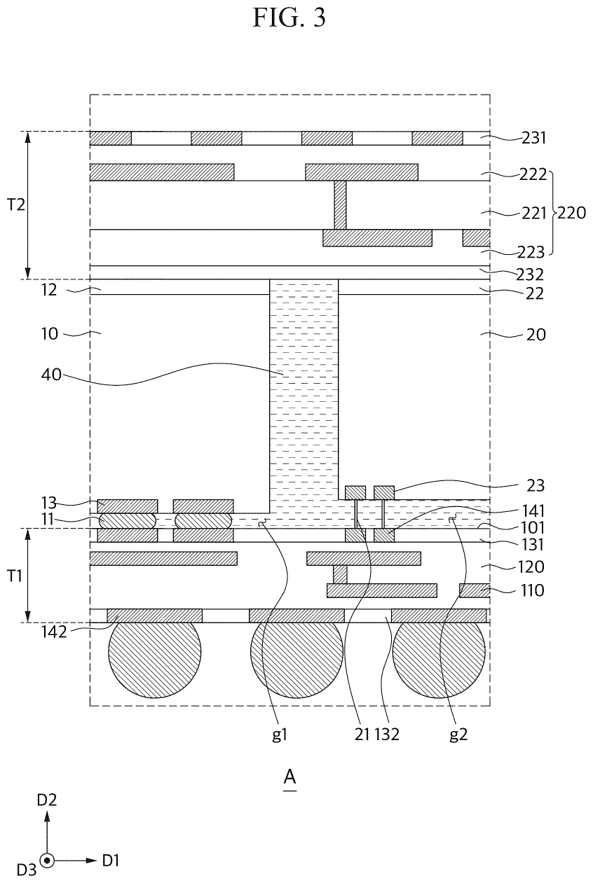

FIG. 3 is an enlarged view of part A of FIG. 2.

Referring to FIG. 1 to FIG. 3, the semiconductor package PK may include a first substrate 100, a first semiconductor chip 10 and a second semiconductor chip 20 placed on the first substrate 100, and a second substrate 200 that is placed on the upper side of the first semiconductor chip 10 and the second semiconductor chip 20 and is electrically connected to the first substrate 100.

In example embodiments, the first substrate 100 may form a base substrate of the semiconductor package PK. In the following description, the first substrate 100 is also called the “base substrate” or “lower substrate.”

In example embodiments, the first substrate 100 may include a first insulation layer 120, a first interconnection structure 110, a first lower passivation layer 132, a first upper passivation layer 131, a first lower connection pad 142 and a first upper connection pad 141.

In example embodiments, for the first insulation layer 120 of the first substrate 100 and the first interconnection structure 110 within the first insulation layer 120, a wiring pattern may be formed to electrically connect the first lower connection pad 142 and the first upper connection pad 141.

In example embodiments, the first insulation layer 120 may include one or more layers. For example, the first insulation layer 120 may have a multiple layer structure formed of an insulating material. Each of the layers constituting the first insulation layer 120 may include an insulating resin. The insulating resin may include a thermosetting resin such as epoxy resin, a thermoplastic resin such as polyimide or a resin impregnated with inorganic filler or/and glass fiber (glass cloth, glass fabric and so on) in such resins. For example, photosensitive resins such as prepreg, ABF, FR-4, BT and/or photo-imageable dielectric (PID) may be included.

In example embodiments, the first upper passivation layer 131 and the first lower passivation layer 132 are protective layers that protect the first substrate 100 from physical and chemical damage, and the layers may correspond to solder resist layers formed using photo solder resist (PSR).

In example embodiments, the first lower connection pad 142 may be formed on the lower surface of the first insulation layer 120. The first lower connection pad 142 may be electrically connected to the first interconnection structure 110. The first lower passivation layer 132 may cover the lower surface of the first insulation layer 120, and expose the first lower connection pad 142 on the lower surface of the first substrate 100.

In example embodiments, the first upper connection pad 141 may be formed on the upper surface of the first insulation layer 120. The first upper connection pad 141 may be electrically connected to the first interconnection structure 110. The first upper passivation layer 131 may cover or at least partially overlap the lower surface of the first insulation layer 120, and expose the first upper connection pad 141 on an upper surface 101 of the first substrate 100.

In example embodiments, each of the first lower connection pad 142 and the first upper connection pad 141 may be electrically connected to the first interconnection structure 110, and the first interconnection structure 110 may include a wiring pattern for electrically connecting the first lower connection pad 142 and the first upper connection pad 141. For example, the first interconnection structure 110 may include a ground (GND) pattern, a power (PWR) pattern, and a signal(S) pattern. For example, the first interconnection structure 110 may include a metal material including copper (Cu), aluminum (Al), silver (Ag), tin (Sn), gold (Au), nickel (Ni), lead (Pb), titanium (Ti), and/or an alloy thereof.

In example embodiments, an external connection terminal 150 may be formed on a lower surface of the first substrate 100 so as to electrically connect the first substrate 100 to an external device. The external connection terminal 150 may be attached to the first lower connection pad 142. The external connection terminal 150 may be a spherical bump or an oval bump, but the specific shape is not limited thereto. The external connection terminal 150 may be made of tin (Sn), indium (In), bismuth (Bi), antimony (Sb), copper (Cu), silver (Ag), zinc (Zn), lead (Pb), and/or combinations thereof. However, the material of the external connection terminal 150 is not limited thereto.

In example embodiments, a plurality of semiconductor chips including the first semiconductor chip 10 and the second semiconductor chip 20 may be arranged on the upper side of the first substrate 100, and may be electrically connected to the first upper connection pad 141 of the first substrate 100. For example, referring to FIG. 2 and FIG. 3, on the upper side of the first substrate 100, the first semiconductor chip 10 and the second semiconductor chip 20 may be arranged spaced apart from each other along the first direction D1 parallel to the surface of the first substrate 100. In the description below, “first direction D1” is the width direction of the semiconductor package PK, and may indicate a direction parallel to the surface of the first substrate 100.

In example embodiments, the first semiconductor chip 10 may be an integrated circuit (IC) in which a plurality of semiconductor devices are integrated.

In example embodiments, the first semiconductor chip 10 may include various types of logic chips such as central processing unit (CPU), graphic processing unit (GPU), field-programmable gate array (FPGA), digital signal processor, cryptographic processor, application processor, analog-digital converter (ADC), application-specific IC (ASIC), or a modem chip. However, the first semiconductor chip 10 is not limited thereto, and may include various memory chips in addition to the various logic chips described above.

In example embodiments, the first semiconductor chip 10 may be connected to the first substrate 100 in a flip-chip configuration. For example, referring to FIG. 2 and FIG. 3, the lower surface of the first semiconductor chip 10 is the active surface, and a plurality of first chip pads 13 may be placed on the lower surface and a first connecting member 11 (also referred to herein as “the conductive bump 11”) may be placed on the first chip pads 13. The upper surface, opposite to the lower surface of the first semiconductor chip 10, may be an inactive surface. Here, the “lower surface” and “upper surface” of the first semiconductor chip 10 are defined based on the direction illustrated in FIG. 2 and FIG. 3. For example, the “lower surface” of the first semiconductor chip 10 may refer to the surface facing the first substrate 100 when the first semiconductor chip 10 is placed within the semiconductor package PK. Further, the “upper surface” of the first semiconductor chip 10 may refer to the opposite surface of the surface facing the first substrate 100 when the first semiconductor chip 10 is placed within the semiconductor package PK.

In example embodiments, the first chip pads 13 may be electrically connected to another component within the first semiconductor chip 10, such as an IC. For example, multiple wiring layers may be formed on the lower surface of the first semiconductor chip 10, and the first chip pads 13 may be electrically connected to the IC inside the first semiconductor chip 10 through multiple wiring layers.

In example embodiments, the second semiconductor chip 20 may be an IC in which a plurality of semiconductor devices are integrated.

In example embodiments, the second semiconductor chip 20 may include a volatile memory chip such as a dynamic random access memory (DRAM) and a static random access memory (SRAM), and nonvolatile memory chips such as flash memory chips, magnetoresistive random access memory (MRAM), and resistive random access memory (RRAM). However, the second semiconductor chip 20 is not limited thereto, and may include various logic chips, including a processor or a modem, in addition to the various memory chips described above.

In example embodiments, the second semiconductor chip 20 may be connected to the first substrate 100 with a wire connection structure with the active surface positioned facing the first substrate 100. For example, referring to FIG. 2 and FIG. 3, the lower surface of the second semiconductor chip 20 is the active surface, and a plurality of second chip pads 23 may be placed on the lower surface and a second connecting member 21 (also referred to herein as “the conductive wire 21”) may be connected to the second chip pads 23. The upper surface, opposite to the lower surface of the second semiconductor chip 20, may be an inactive surface. Here, the “lower surface” and “upper surface” of the second semiconductor chip 20 are defined based on the direction illustrated in FIG. 2 and FIG. 3. For example, the “lower surface” of the second semiconductor chip 20 may refer to the surface facing the first substrate 100 when the second semiconductor chip 20 is placed within the semiconductor package PK. Further, the “upper surface” of the second semiconductor chip 20 may refer to the opposite surface of the surface facing the first substrate 100 when the second semiconductor chip 20 is placed within the semiconductor package PK.

In example embodiments, the second chip pad 23 may be electrically connected to another component within the second semiconductor chip 20, such as an IC. For example, multiple wiring layers may be formed on the lower surface of the second semiconductor chip 20, and the second chip pad 23 may be electrically connected to an IC inside the second semiconductor chip 20 through the multiple wiring layers.

In example embodiments, any two of the plurality of semiconductor chips arranged on the upper side of the first substrate 100 may be different types of semiconductor chips. For example, the first semiconductor chip 10 and the second semiconductor chip 20 illustrated in FIGS. 1 to 3 may be different types of semiconductor chips. However, in contrast, the first semiconductor chip 10 and the second semiconductor chip 20 may be the same type of semiconductor chips.

A plurality of semiconductor chips including the first semiconductor chip 10 and the second semiconductor chip 20 may be disposed between the first substrate 100 and the second substrate 200. The plurality of semiconductor chips may be disposed adjacent to each other in a second direction D2 perpendicular to the upper surface 101 of the first substrate 100. In the following description, the second direction D2 is a direction perpendicular to the first direction D1, and may be a direction perpendicular to the upper surface 101 of the first substrate 100 and a height direction (or thickness direction) of the semiconductor package PK.

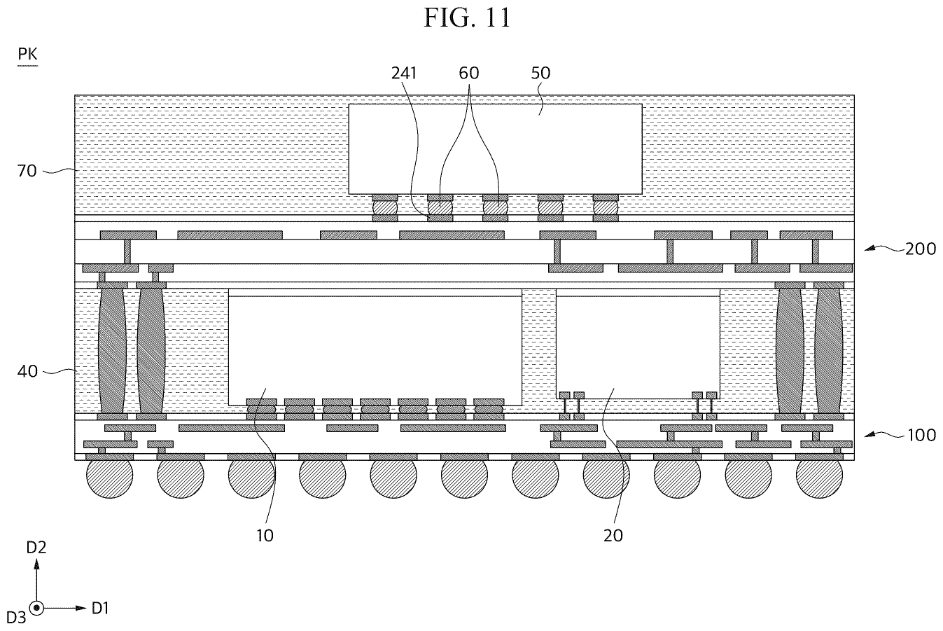

In example embodiments, the second substrate 200 may be an interposer substrate. For example, the semiconductor package PK may have a so-called Interposer Package On Package (IPOP) structure in which multiple semiconductor devices (for example, semiconductor chips or semiconductor sub-packages) are stacked with the second substrate 200 therebetween. For example, a semiconductor chip (for example, a third semiconductor chip 50 in FIG. 11) or a semiconductor package may be placed on the upper portion of the second substrate 200 illustrated in FIGS. 2 and 3. In the description below, the second substrate 200 is also referred to as the “interposer substrate.”

In example embodiments, the second substrate 200 may be configured as a PCB, a ceramic substrate, or a substrate for a wafer level package manufactured at the wafer level.

In example embodiments, a second insulation layer 220 of the second substrate 200 and a second interconnection structure 210 within the second insulation layer 220 may be included. The second interconnection structure 210 may form a wiring pattern for electrically connecting a second lower connection pad 242 and a second upper connection pad 241.

In example embodiments, the second insulation layer 220 may include one or more layers. For example, the second insulation layer 220 may have a structure in which a lower insulation layer 223 and a second lower passivation layer 232 are laminated on the lower surface of a core layer 221 and an upper insulation layer 222 and a second upper passivation layer 231 are laminated on the upper surface of the core layer 221, where the layers have high structural rigidity.

In example embodiments, each of the layers constituting the second insulation layer 220 may include an insulating resin. The insulating resin may include a thermosetting resin such as epoxy resin, a thermoplastic resin such as polyimide or a resin impregnated with inorganic filler or/and glass fiber (glass cloth, glass fabric and so on) in such resins. For example, photosensitive resins such as prepreg, ABF, FR-4, BT and/or photo-imageable dielectric (PID) may be included.

Further, in example embodiments, the second upper passivation layer 231 and the second lower passivation layer 232 are protective layers that protect the second substrate 200 from physical and chemical damage, and may correspond to solder resist layers formed using PSR.

In example embodiments, the second interconnection structure 210 may be electrically connected to each of the second lower connection pad 242 and the second upper connection pad 241. For example, the second interconnection structure 210 may include a metal material including copper (Cu), aluminum (Al), silver (Ag), tin (Sn), gold (Au), nickel (Ni), lead (Pb), titanium (Ti), and/or an alloy thereof.

In example embodiments, the second upper connection pad 241 may be formed on the upper surface of the second insulation layer 220. The second upper connection pad 241 may be electrically connected to the second interconnection structure 210. The second upper passivation layer 231 may cover or at least partially overlap the upper surface of the upper insulation layer 222, and may expose the second upper connection pad 241.

In example embodiments, the second lower connection pad 242 may be formed on the lower surface of the second insulation layer 220. The plurality of semiconductor chips (the first semiconductor chip 10 and the second semiconductor chip 20) or a conductive connector 30 positioned between the first substrate 100 and the second substrate 200 may be electrically connected to the second lower connection pad 242.

In example embodiments, the semiconductor package PK may have a multi-chip structure. In other words, the plurality of semiconductor chips (the first semiconductor chip 10 and the second semiconductor chip 20) between the first substrate 100 and the second substrate 200 may be arranged along a direction parallel to the upper surface 101 of the first substrate 100 (for example, the first direction D1) between any two conductive connectors 30 of the semiconductor package PK. For example, referring to the layout drawing illustrated in FIG. 1, the first semiconductor chip 10 and the second semiconductor chip 20 of the semiconductor package PK may be arranged side by side along (or spaced apart in) the first direction D1 in the inner area of a plurality of conductive connectors arranged along the edge of the semiconductor package PK. Further, referring to FIG. 2, the first semiconductor chip 10 and the second semiconductor chip 20 may be arranged side by side in the first direction D1 along a lower surface 201 of the second substrate 200.

In example embodiments, each of the first semiconductor chip 10 and the second semiconductor chip 20 may be attached to the second substrate 200. For example, referring to FIG. 2 and FIG. 3, the upper surface of the first semiconductor chip 10 and the upper surface of the second semiconductor chip 20 may be attached to the lower surface 201 of the second substrate 200. Accordingly, the first semiconductor chip 10 and the second semiconductor chip 20 may be fixed on the lower surface 201 of the second substrate 200.

In example embodiments, an adhesive member (a first adhesive member 12 and a second adhesive member 22) may be interposed between the first semiconductor chip 10 and the second substrate 200, and between the second semiconductor chip 20 and the second substrate 200. For example, referring to FIG. 2 and FIG. 3, the first adhesive member 12 may be placed between the upper surface of the first semiconductor chip 10 and the lower surface 201 of the second substrate 200, and the second adhesive member 22 may be placed between the upper surface of the second semiconductor chip 20 and the lower surface 201 of the second substrate 200.

In example embodiments, the first adhesive member 12 and the second adhesive member 22 may be adhesive films. For example, the adhesive film may be a die attach film. The die attach film may be an inorganic adhesive or a polymer adhesive.

In example embodiments, with regard to the first semiconductor chip 10, the opposite surface (for example, the lower surface) of one surface (for example, the upper surface) attached to the second substrate 200 is the active surface. The plurality of first chip pads 13 used for electrical connection with the first substrate 100 may be arranged on the opposite surface of the first semiconductor chip 10. In other words, with regard to the first semiconductor chip 10, one surface may be attached and fixed to the lower surface 201 of the interposer substrate (in other words, the second substrate 200), and the first semiconductor chip 10 may be electrically connected to the first interconnection structure 110 of the first substrate 100 via the first connecting member 11 disposed between the opposite surface and the first substrate 100.

In example embodiments, with regard to the second semiconductor chip 20, the other surface (for example, the lower surface) opposite to one surface (for example, the upper surface) attached to the second substrate 200 is the active surface, and the plurality of second chip pads 23 used for electrical connection with the first substrate 100 may be arranged on the other surface of the second semiconductor chip 20. In other words, the second semiconductor chip 20 may be fixed by having one surface attached to the lower surface of the interposer substrate (in other words, the second substrate 200), and may be electrically connected to the first interconnection structure 110 of the first substrate 100 through the second connecting member 21 positioned between the opposite surface and the first substrate 100.

In order to implement the connection structure of the first semiconductor chip 10 and the second semiconductor chip 20 described above, the semiconductor package PK according to the embodiments may be manufactured in a method in which the first semiconductor chip 10 and the second semiconductor chip 20 are placed on the surface (for example, the lower surface 201) of the second substrate 200, and then the first substrate 100 is formed at a position facing the active surface of the first semiconductor chip 10 and the active surface of the second semiconductor chip 20. In this case, the first substrate 100 may be a redistributed substrate (e.g., a redistribution substrate) including a redistributed/redistribution layer manufactured in the redistributing/redistribution process. It should be understood that the terms “redistributed” and “redistribution” may be referred to interchangeably herein.

In example embodiments, at least one of the first semiconductor chip 10 and the second semiconductor chip 20 may be electrically connected to the first upper connection pad 141 of the first substrate 100 through a conductive wire 21. For example, referring to FIG. 2 and FIG. 3, the second chip pad 23 of the second semiconductor chip 20 and the first upper connection pad 141 of the first substrate 100 may be electrically connected to each other by the conductive wire 21. The conductive wire 21 may include a metal material including gold (Au), silver (Ag), copper (Cu), aluminum (Al), tin (Sn), nickel (Ni), lead (Pb), titanium (Ti), and/or an alloy thereof.

In example embodiments, with respect to the semiconductor chip (the first semiconductor chip 10 and the second semiconductor chip 20), since the active surface is placed facing the first substrate 100, the chip pad (the first chip pad 13 and the second chip pad 23) of the semiconductor chip (the first semiconductor chip 10 and the second semiconductor chip 20) and the first upper connection pad 141 of the first substrate 100 may be electrically connected through a connecting member having a length corresponding roughly to the space (for example, a space g1 and a space g2 in FIG. 3) between the semiconductor chip (the first semiconductor chip 10 and the second semiconductor chip 20) and the first substrate 100. With the connection structure, the length of the connection member (for example, the conductive wire 21) connecting the semiconductor chip and the first substrate 100 may be drastically or substantially reduced.

In the case of the existing wire bonding structure applied to the semiconductor package PK, with respect to the semiconductor chip, the surface opposite to the active surface is attached to the lower substrate, the wire is bent so that one end is connected to the active surface of the semiconductor chip and the other end is connected to the lower substrate beneath the semiconductor chip. In other words, the wire extends from the active surface of the semiconductor chip and runs along the side of the semiconductor chip to the lower substrate located underneath. According to the existing wire connection structure, since the wire is exposed for a long distance from the upper surface of the semiconductor chip to the upper surface of the lower substrate, the wire may be damaged during subsequent processes (for example, the process of filling the molding layer). Further, in order to secure a safety space between the interposer substrate placed on the upper side of the semiconductor chip and the top of the wire, the interposer substrate and the semiconductor chip must be placed at a distance greater than a specified distance, and thus the height of the entire semiconductor package PK increases. Further, since the wire extends along the side of the semiconductor chip, when another semiconductor chip is placed additionally, in order to secure wire placement space, a gap of a certain distance or greater must be formed between two semiconductor chips, and according thereto the length of the semiconductor package PK (for example, the length of the first direction D1) is increased.

However, according to example embodiments of the present disclosure, in the semiconductor package PK, each of the first semiconductor chip 10 and the second semiconductor chip 20, which are arranged side by side in the length direction of the semiconductor package PK (in other words, the first direction D1), may be attached to the second substrate 200 located on the upper side, each active surface may face the first substrate 100 in order for the length of a connecting member (for example, the conductive wire 21) for electrical connection between the first substrate 100 and the semiconductor chip to be formed very short or to have a relatively smaller length. For example, as illustrated in FIG. 2 and FIG. 3, the conductive wire 21 may connect the second chip pad 23 of the second semiconductor chip 20 and the first upper connection pad 141 of the first substrate 100 with the shortest distance. As such, as the length of the conductive wire 21 is shortened, the electrical resistance may be minimized, and since the exposed area of the conductive wire 21 is also reduced, the risk of damage to the conductive wire 21 during subsequent processes may also be reduced.

Further, since there is no need to secure a safety space between the wire and the interposer substrate as in conventional packages, the first substrate 100, the semiconductor chip, and the second substrate 200 may be placed relatively closer to each other, and thus the height (or thickness) of the entire semiconductor package PK may be reduced.

Further, as illustrated in FIG. 2 and FIG. 3, since the conductive wire 21 of the second semiconductor chip 20 is connected in a straight line from the second chip pad 23 to the base substrate 100 in the second direction D2 and does not extend beyond the edge of the second semiconductor chip 20 to the side of the second semiconductor chip 20, no space is required for the conductive wire 21 between the two semiconductor chips (the first semiconductor chip 10 and the second semiconductor chip 20), and thus the two semiconductor chips may be placed very closely adjacent to each other. Therefore, compared to the existing semiconductor package PK structure that required a certain spacing for wire placement, the length of the entire semiconductor package PK (for example, the length of first direction D1) may be reduced. Further, according to example embodiments of the present disclosure, as the length of the entire semiconductor package PK decreases, the warpage phenomenon caused by the difference in coefficient of thermal expansion of each component (for example, layer elements such as the first substrate 100, the molding layer, the second substrate 200 of the semiconductor package PK) of the semiconductor package PK may be alleviated.

Meanwhile, FIG. 2 and FIG. 3 illustrate the structure in which the first semiconductor chip 10 is electrically connected to the first upper connection pad 141 of the first substrate 100 via the conductive bump 11 and the second semiconductor chip 20 is electrically connected to the first upper connection pad 141 of the first substrate 100 via the conductive wire 21. However, unlike what is illustrated, in the semiconductor package PK according to some example embodiments, both the first semiconductor chip 10 and the second semiconductor chip 20 may be connected to the first substrate 100 via the conductive bumps 11, or via the conductive wire 21.

In example embodiments, for the first substrate 100 including a redistributed substrate or a redistributed layer, the core layer 221 may be omitted to reinforce structural rigidity, unlike the second substrate 200. In other words, the first substrate 100 may be formed by stacking a wiring layer and an insulating layer without a separate core layer 221. In this case, as illustrated in FIG. 3, the thickness T1 in the second direction D2 of the first substrate 100 may be thinner or less than the thickness T2 in the second direction D2 of the second substrate 200 on which the core layer 221 is provided.

In example embodiments, the semiconductor package PK may further include the plurality of conductive connectors 30 electrically connecting the first substrate 100 and the second substrate 200.

In example embodiments, the conductive connector 30 may be interposed between the first substrate 100 and the second substrate 200. The conductive connector 30 may contact the upper surface 101 of the first substrate 100 and the lower surface 201 of the second substrate 200. The conductive connector 30 may electrically connect the first substrate 100 and the second substrate 200. For example, the conductive connector 30 may contact the first upper connection pad 141 of the first substrate 100 and the second lower connection pad 242 of the second substrate 200. Accordingly, the conductive connector 30 may electrically connect the first interconnection structure 110 of the first substrate 100 and the second interconnection structure 210 of the second substrate 200.

In example embodiments, the conductive connector 30 may include a bump shape, a pillar shape, and so on. The conductive connector 30 may include nickel (Ni), antimony (Sb), bismuth (Bi), zinc (Zn), indium (In), palladium (Pd), platinum (Pt), aluminum (Al), copper (Cu), molybdenum (Mo), titanium (Ti), gold (Au), silver (Ag), chromium (Cr), and/or tin (Sn), but may also be formed of various other suitable materials. For example, the conductive connector 30 may be formed through a solder ball process or a metal post process made of copper (Cu). However, the shape or manufacturing process of the conductive connector 30 is not limited thereto. The conductive connector 30 may be implemented in any structure as long as it electrically connects the first interconnection structure 110 of the first substrate 100 and the second interconnection structure 210 of the second substrate 200.

In example embodiments, a molding layer 40 may be placed between the first substrate 100 and the second substrate 200. The molding layer 40 may at least partially fill the space between the first substrate 100 and the second substrate 200. Accordingly, the molding layer 40 may cover or at least partially overlap the first substrate 100, the first semiconductor chip 10, the second semiconductor chip 20, the conductive connector 30 and so on, and protect them from the external environment. The molding layer 40 may be made of a molding material such as epoxy molding compound (EMC), epoxy resin, UV resin, polyurethane resin, silicone resin, silica filler, and so on. However, the molding material consisting the molding layer 40 is not limited thereto.

In example embodiments, the molding layer 40 may be formed to be thick enough to cover or overlap the lower surfaces of both the first semiconductor chip 10 and the second semiconductor chip 20 while the first semiconductor chip 10 and the second semiconductor chip 20 are attached to the second substrate 200, and then a portion may be ground and removed before the subsequent process of electrically connecting the first semiconductor chip 10 and the second semiconductor chip 20 to the first substrate 100. For example, the molding layer 40 illustrated in FIGS. 2 and 3 may represent the molding layer 40 after grinding is completed. As such, in the process of grinding a portion of the molding layer 40, the connecting members (the first connecting member 11 and the second connecting member 21) connected to the first semiconductor chip 10 and the second semiconductor chip 20 may be exposed through the surface of the molding layer 40, and the first upper connection pad 141 of the first substrate 100 may be electrically connected to the exposed connecting member (the first connecting member 11 and the second connecting member 21).

Further, according to the manufacturing method, the molding layer 40 formed of the same molding material may be placed in the space g1 between the first semiconductor chip 10 and the first substrate 100 and in the space g2 between the second semiconductor chip 20 and the second substrate 200. For example, referring to FIG. 3, the molding layer 40 arranged in the space between the plurality of conductive bumps 11 connected to the first semiconductor chip 10 and the molding layer 40 arranged between the plurality of conductive wires 21 connected to the second semiconductor chip 20 may be formed of the same molding material. This will be explained in detail in the semiconductor package PK manufacturing process described later.

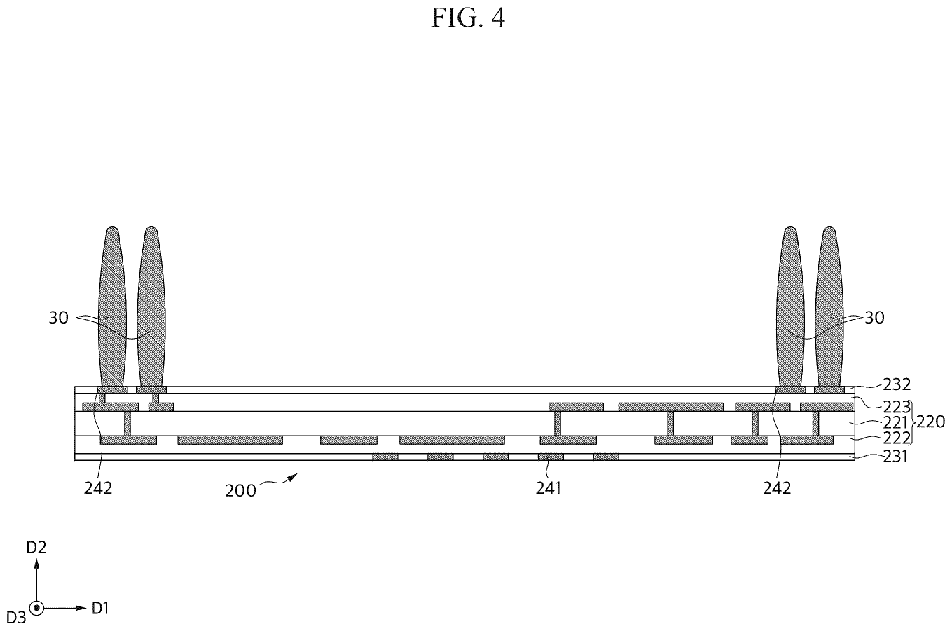

Hereinafter, a method for manufacturing the semiconductor package PK according to example embodiments will be described in detail with reference to FIGS. 4 to 11.

The semiconductor package PK manufactured through the process described in FIGS. 4 to 11 may correspond to the semiconductor package PK described above through FIGS. 1 to 3, and thus any description overlapping with FIGS. 1 to 3 may be omitted.

FIG. 4 is a cross-sectional view illustrating the plurality of conductive connectors 30 formed on the second substrate 200.

First, referring to FIG. 4, the second substrate 200 including the second insulation layer 220 and the second interconnection structure 210 may be formed. The second substrate 200 may serve as an interposer substrate in the semiconductor package PK. The second upper passivation layer 231 and the second lower passivation layer 232 may be arranged on both sides of the second insulation layer 220 of the second substrate 200, and the second upper connection pad 241 and the second lower connection pad 242 are exposed.

In example embodiments, the second substrate 200 may be prepared with its upper surface and lower surface inverted (or rotated) to place the first semiconductor chip 10 and the second semiconductor chip 20.

In example embodiments, the conductive connector 30 may be formed extending in a direction perpendicular to the surface of the inverted second substrate 200. The conductive connector 30 may be electrically connected to some of the second lower connection pads 242 of the second substrate 200.

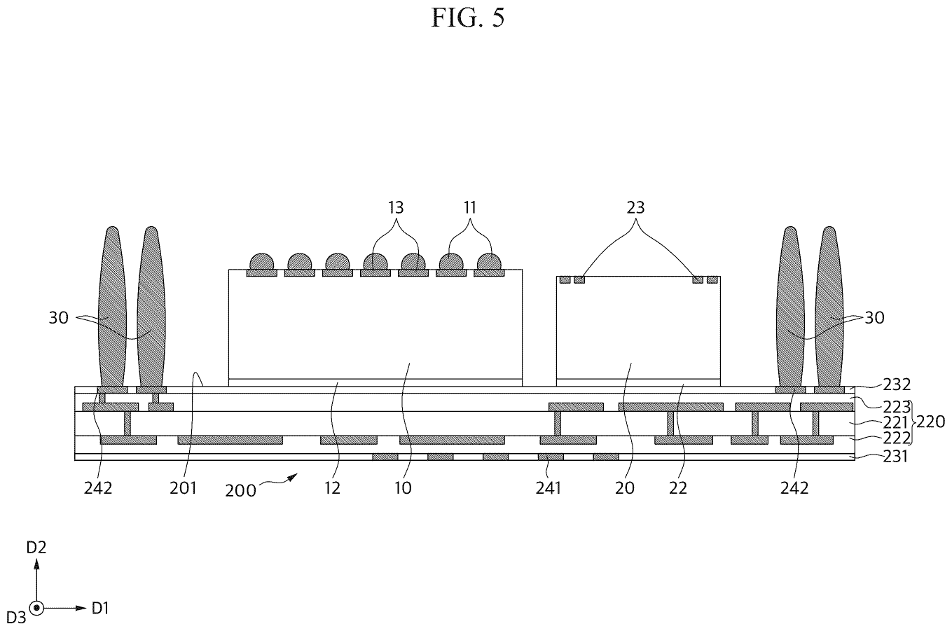

FIG. 5 is a cross-sectional view illustrating the first semiconductor chip 10 and the second semiconductor chip 20 attached to the second substrate 200.

Referring to FIG. 5, the first semiconductor chip 10 and the second semiconductor chip 20 are attached to the second substrate 200. In this operation, the second substrate 200 (in other words, the interposer substrate) may be upside down. Therefore, as illustrated in FIG. 2, based on the finally manufactured semiconductor package PK, the first semiconductor chip 10 and the second semiconductor chip 20 may be attached to the lower surface 201 of the second substrate 200.

In example embodiments, the first semiconductor chip 10 attached to the second substrate 200 may be configured to be electrically connected to other components via the conductive bumps 11, and the second semiconductor chip 20 may be configured to be electrically connected to other components by the conductive wires 21 connected thereto in a subsequent process. For example, the first semiconductor chip 10 could be a logic chip such as a modem chip and a processor chip, and the second semiconductor chip 20 may be a memory chip.

In example embodiments, an adhesive member (the first adhesive member 12, for example, an adhesive film) is interposed between one surface of the first semiconductor chip 10 and the second substrate 200, and an adhesive member (the second adhesive member 22, for example, an adhesive film) is interposed between one surface of the second semiconductor chip 20 and the second substrate 200. The first semiconductor chip 10 and the second semiconductor chip 20 may be fixed to the second substrate 200 via adhesive members (the first adhesive member 12 and the second adhesive member 22).

According to some example embodiments, the adhesive members (the first adhesive member 12 and the second adhesive member 22) may be attached to the opposite surface of the active surface in a semiconductor chip. Therefore, as illustrated in FIG. 5, the first semiconductor chip 10 and the second semiconductor chip 20 may be attached to the second substrate 200 with each chip pad (the first chip pad 13 and the second chip pad 23) exposed toward the upper side.

In example embodiments, when the adhesive members (the first adhesive member 12 and the second adhesive member 22) are provided as adhesive films, the adhesive films may be attached to a wafer before being cut into semiconductor chips (the first semiconductor chip 10 and the second semiconductor chip 20) in a semi-cured state, and then in the process of dividing the wafer into individual semiconductor chips (the first semiconductor chip 10 and the second semiconductor chip 20), the adhesive films may be cut together or concurrently with the semiconductor chips (the first semiconductor chip 10 and the second semiconductor chip 20). Therefore, the adhesive films may have areas corresponding to the semiconductor chips (the first semiconductor chip 10 and the second semiconductor chip 20) to which the adhesive films are attached.

In example embodiments, the adhesive film may be a thermosetting adhesive film. In this case, the first semiconductor chip 10 and the second semiconductor chip 20 may be bonded or attached to the second substrate 200 by applying heat to the adhesive film and hardening the adhesive film in close contact with the second substrate 200.

In example embodiments, the lower surface 201 of the second substrate 200 to which the first semiconductor chip 10 and the second semiconductor chip 20 are attached may be formed as a flat (or substantially flat) surface. Therefore, one surface of the first semiconductor chip 10 and one surface of the second semiconductor chip 20 attached to the second substrate 200 may be arranged on the same plane.

Meanwhile, the first semiconductor chip 10 may be attached to the second substrate 200 with the first connecting member 11 being connected to the first chip pad 13. However, when the first connecting member 11 is not connected to the first chip pad 13, an additional operation of bonding the first connecting member 11 to the first chip pad 13 of the first semiconductor chip 10 may be performed before or after attaching the first semiconductor chip 10 to the second substrate 200.

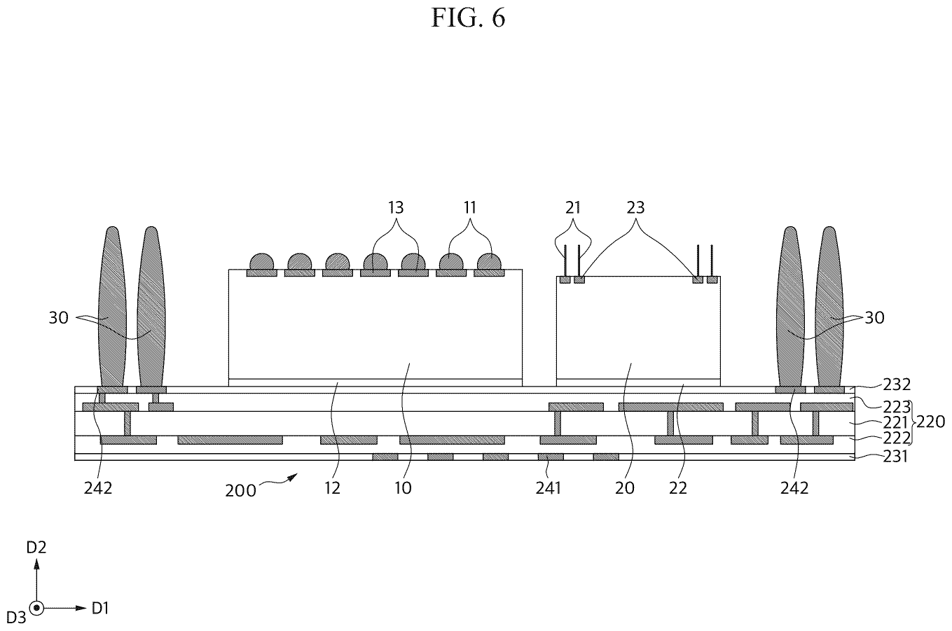

FIG. 6 is a cross-sectional view illustrating the conductive wire 21 connected to the second semiconductor chip 20.

Referring to FIG. 6, the second connecting member 21 may be connected to the second chip pad 23 of the second semiconductor chip 20. For example, the second connecting member 21 may be the conductive wire 21.

In example embodiments, the conductive wire 21 may be connected to the second chip pad 23 so as to be approximately vertical in a direction perpendicular to the lower surface 201 of the second substrate 200 (for example, the second direction D2).

In example embodiments, each of the conductive wires 21 connected to the plurality of second chip pads 23 may be arranged parallel to one another.

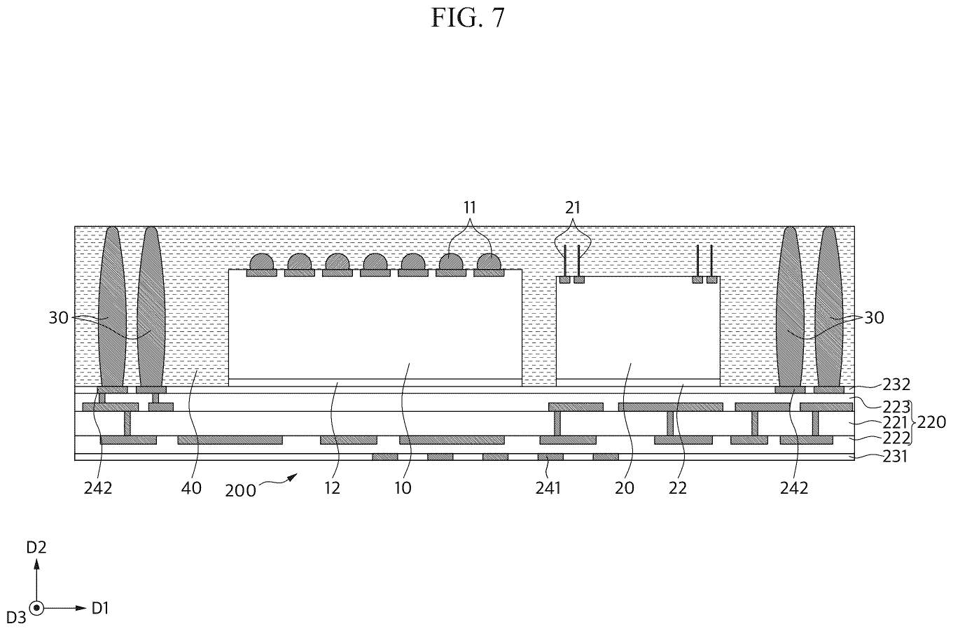

FIG. 7 is a cross-sectional view illustrating the molding layer 40 formed on the second substrate 200.

Referring to FIG. 7, the molding layer 40 may be formed on the second substrate 200 to sufficiently cover or overlap the first semiconductor chip 10 and the second semiconductor chip 20.

In example embodiments, the process of forming the molding layer 40 may include a compression molding process or a transfer molding process.

In example embodiments, the molding layer 40 may cover (or overlap) and seal the first semiconductor chip 10, the second semiconductor chip 20, and the connecting members (the first connecting member 11 and the second connecting member 21) connected to each semiconductor chip (the first semiconductor chip 10 and the second semiconductor chip 20). For example, referring to FIG. 7, the molding layer 40 may not only cover or overlap the conductive wire 21 connected to the second semiconductor chip 20, but also cover or overlap the multiple conductive bumps 11 connected to the first semiconductor chip 10. As such, the active surfaces of the first semiconductor chip 10, the active surfaces of the second semiconductor chip 20 and the connecting members (the first connecting member 11 and the second connecting member 21) may be covered with or overlapped by the molding layer 40 made of the same material, and as such, the active surfaces of the semiconductor chips can all be covered or overlapped through a single molding process.

With regard to the existing POP structure, when the substrate and the semiconductor chip are connected by multiple small bumps, a separate molding process is required to fill this gap since the gap between the substrate and the semiconductor chips is narrow. For example, in the molding process of existing POP structure, a first molding process (so-called the underfill process) is performed and includes filling a narrow space between the substrate and the semiconductor chip with a molding material made of small particles. Thereafter, a second molding process is performed, which includes filling a space between the lower substrate and the interposer substrate with another molding material consisting of large particles.

Unlike the existing structure, in the case of the semiconductor package PK according to example embodiments of the present disclosure, the molding process may be performed before connecting the semiconductor chip (the first semiconductor chip 10 and the second semiconductor chip 20) and the base substrate 100, and thus a separate molding process, which is filling the narrow space between the semiconductor chip and the substrate included in the existing case, may be omitted. In other words, since multiple semiconductor chips (the first semiconductor chip 10 and the second semiconductor chip 20) may be covered or overlapped at once using one type of molding material in a single molding process, the molding process may be simplified and the efficiency and manufacturing economy may be improved.

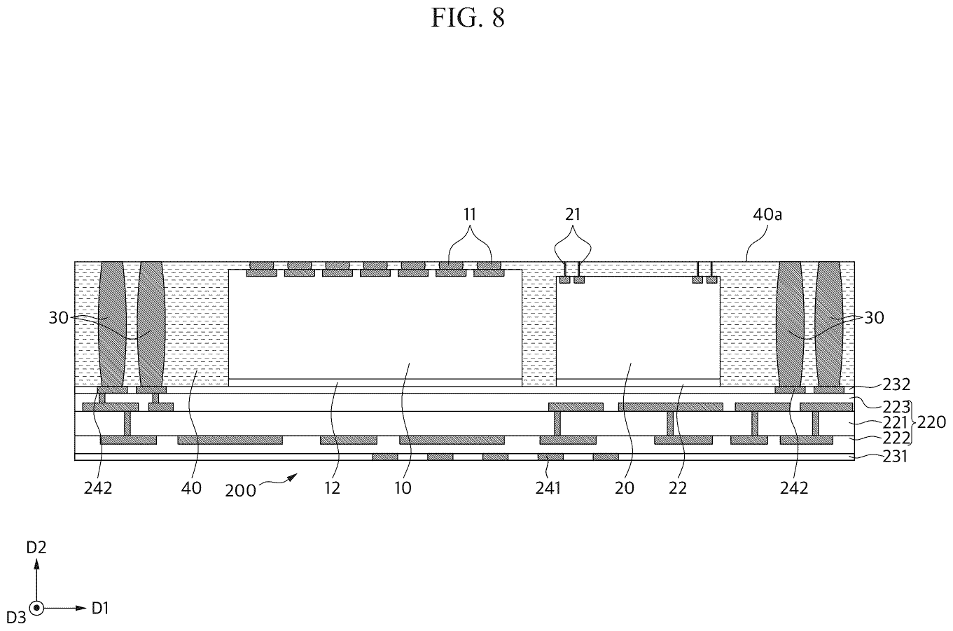

FIG. 8 is a cross-sectional view illustrating a flat (or substantially flat) molding surface 40a formed by grinding a portion of the molding layer 40.

Referring to FIG. 7, in the molding process, the molding layer 40 may be formed thick enough to cover or overlap the connecting members (the first connecting member 11 and the second connecting member 21) connected to each semiconductor chip (the first semiconductor chip 10 and the second semiconductor chip 20), and through the grinding process of cutting off a portion of the formed molding layer 40, the flat molding surface 40a may be formed with exposed connecting members (the first connecting member 11 and the second connecting member 21) as illustrated in FIG. 8. In the grinding process, a portion of the molding layer 40 and a portion of the connecting member (the first connecting member 11 and the second connecting member 21) may be removed, and when the grinding process is complete, the conductive connector 30, the conductive bump 11 and the conductive wire 21 may have exposed surfaces formed on the flat molding surface 40a.

In example embodiments, the exposed surface of the conductive bump 11, the exposed surface of the conductive wire 21, the exposed surface of the conductive connector 30, and the flat molding surface 40a may be coplanar with each other. For example, the exposed surface of the conductive bump 11, the exposed surface of the conductive wire 21, and the flat molding surface 40a may be positioned substantially on the same plane.

In example embodiments, the molding layer 40 is cured while wrapping or extending around the upright conductive wire 21, and then the grinding process is performed, and thus after the grinding process, the conductive wire 21 may be exposed in an upright state with its end face through the flat molding surface 40a.

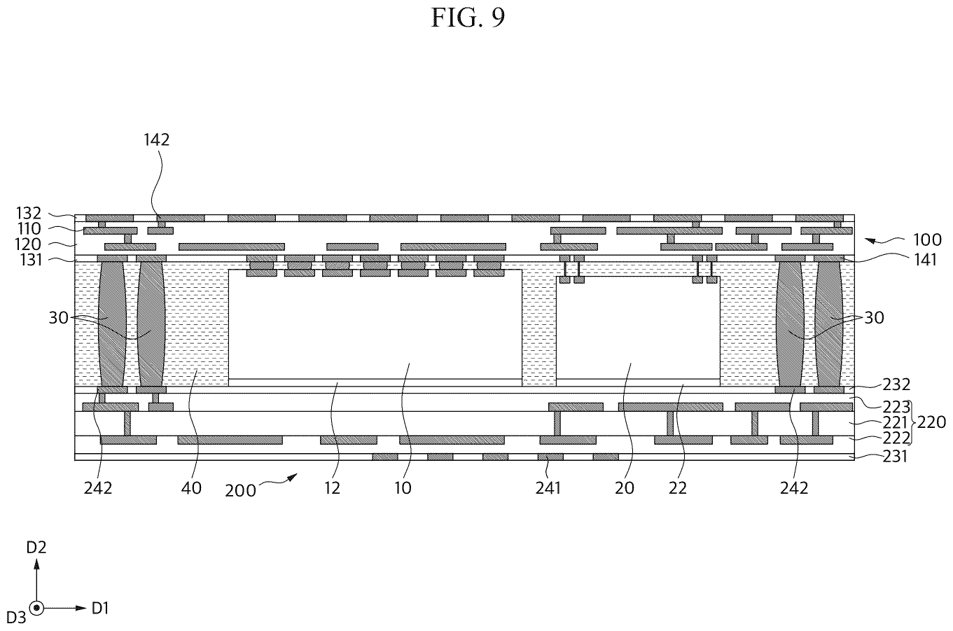

FIG. 9 is a cross-sectional view illustrating the first substrate 100 formed on the molding layer 40.

Referring to FIG. 9, the first substrate 100 used as a base substrate may be formed on the flat molding surface 40a, (see FIG. 8). For example, the first substrate 100 may be a redistributed substrate including a redistributed layer formed through a redistributing process.

In example embodiments, the first substrate 100 may include the first insulation layer 120 and a conductive line formed within the first insulation layer 120 (in other words, the first interconnection structure 110).

In example embodiments, the first substrate 100 may be formed by alternately repeating the process of forming a metal pattern to electrically connect with the conductive connector 30, the first connecting member 11 and the second connecting member 21 exposed on the flat molding surface 40a, and forming an insulating layer including an inorganic dielectric substance such as a polymer and silicon oxide on the upper side of the first substrate 100. A portion of the metal pattern formed in this way may become the first upper connection pad 141, another portion of the metal pattern may be the first interconnection structure 110, and another portion of the metal pattern may be the first lower connection pad 142 (also referred to herein as the “external connection pad”). Further, the insulating layer formed between the metal patterns may be the first insulation layer 120. Accordingly, as illustrated in FIG. 9, the first substrate 100 may be formed in which the first upper connection pad 141 is connected to the conductive connector 30, the first connecting member 11 and the second connecting member 21, and the first lower connection pad 142 is exposed on the upper side.

In example embodiments, the metal pattern may be formed by performing the method of performing an electrolytic plating process after forming a seed metal layer or the sputtering process.

In example embodiments, the insulation layer may be formed through the process such as chemical vapor deposition (CVD), atomic layer deposition (ALD), and plasma-enhanced chemical vapor deposition (PECVD).

In example embodiments, after the formation of the first insulation layer 120 and the first interconnection structure 110 is completed, the first lower passivation layer 132 may be formed on the upper side of the first insulation layer 120. The first lower passivation layer 132 may have multiple openings exposing the first lower connection pad 142 to the outside.

In example embodiments, the first upper connection pad 141 of the first substrate 100 may be formed to face the second chip pad 23 of the second semiconductor chip 20 in the second direction D2 so that the conductive wire 21 may be connected in an upright state.

Meanwhile, as described with respect to the operation of forming the molding layer 40, since the same molding material is filled or deposited between the first substrate 100 and the first semiconductor chip 10 connected through the plurality of conductive bumps 11, and between the first substrate 100 and the second semiconductor chip 20 connected through the conductive wire 21 in the semiconductor package PK according to the embodiments, the surface facing the first semiconductor chip 10 and the second semiconductor chip 20 in the first substrate 100 may be formed as a flat (or substantially flat) surface with the guide structures required for forming the molding layer 40 omitted using different molding materials.

For example, in the existing package manufacturing method in which multiple molding processes using different molding materials are performed sequentially, it is desirable to form a guide structure, such as a protruding dam, on the upper surface of the substrate in order for the molding material injected in the preceding molding process to stay or remain only in the target area (for example, the lower portion area of a specific semiconductor chip).

However, according to example embodiments of the present disclosure, in the method of manufacturing the semiconductor package PK, since a single molding process is performed using the same molding material, the guide structure that causes the molding material to remain only in a local area on the substrate may be omitted for the first substrate 100. As the separate structure is omitted, the first semiconductor chip 10 and the second semiconductor chip 20 may be placed closer together, and thus the size of the semiconductor package PK may be further reduced.

Further, with respect to the single molding layer 40 formed from the same material, since there is no possibility of peeling occurring at the interface of different molding layers, the stability of the semiconductor package PK may be further increased.

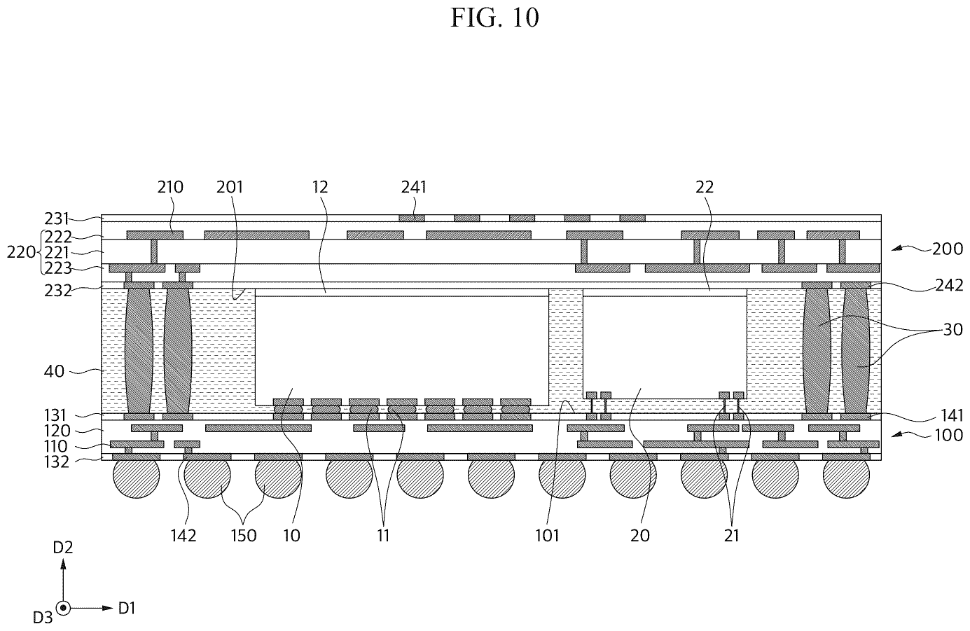

FIG. 10 is a cross-sectional view illustrating that after the first substrate 100, the molding layer 40 and the second substrate 200 are mutually bonded (e.g., bonded or connected to each other) and turned over or rotated, the external connection terminal 150 is formed on the lower portion of the first substrate 100.

Referring to FIG. 9 and FIG. 10 together, after the formation of the first substrate 100 is completed, the entire structure of the first substrate 100, the molding layer 40 and the second substrate 200 that are mutually fixed may be turned over, and alignment may be implemented in the order of the first substrate 100, the molding layer 40 and the second substrate 200 from below.

While the turning-over (or rotation) operation being performed, or before or after the turning-over operation, the process of bonding the external connection terminal 150 to the first lower connection pad 142 of the first substrate 100 may be performed. For example, the external connection terminal 150 may be a bump-shaped structure formed of a conductive material.

The above series of processes may be summarized schematically as follows.

The method of manufacturing the semiconductor package PK according to example embodiments of the present disclosure may include forming the plurality of conductive connectors 30 extending in a direction perpendicular to the surface of the interposer substrate 200, attaching one surface of the first semiconductor chip 10 and one surface of the second semiconductor chip 20 to the surface of the interposer substrate 200, bonding the second connecting member 21 to the other surface opposite to one surface of the second semiconductor chip 20, forming the molding layer 40 covering or overlapping the other surface of the first semiconductor chip 10 and the other surface of the second semiconductor chip 20 on the surface of the interposer substrate 200, cutting off or removing a portion of the molding layer 40 to form the flat (or substantially flat) molding surface 40a, and forming (or providing) the base substrate 100 on the flat molding surface 40a.

Further, according to the method of manufacturing the semiconductor package PK according to example embodiments of the present disclosure, the first connecting member 11 may be formed by the conductive bump 11, and the second connecting member 21 may be the conductive wire 21 extending in a direction perpendicular to the other surface of the second semiconductor chip 20.

Further, in the method of manufacturing the semiconductor package PK according to example embodiments, forming the first substrate 100, which is the base substrate 100, may include forming a metal pattern electrically connected to the first connecting member 11 and the second connecting member 21, covering or overlapping at least a portion of the metal pattern with an insulation layer (e.g., providing an insulation layer on at least a portion of the metal pattern), and forming the external connection pad 142 electrically connected to a metal pattern on the opposite side of the surface facing the first connecting member 11 and the second connecting member 21 in the insulation layer. In some embodiments, the method may include providing the base substrate 100 (e.g., a separately fabricated base substrate 100) on the flat molding surface 40a.

Further, the method of manufacturing the semiconductor package PK according to example embodiments may include turning over the interposer substrate 200, the molding layer 40, and the base substrate 100 that are mutually bonded (e.g., bonded or connected to each other), and bonding the external connection terminal 150 to the external connection pad 142 of the base substrate 100.

Meanwhile, the method of manufacturing the semiconductor package PK according to example embodiments may further include a third semiconductor placed on the upper side of the second substrate 200. For example, the method of manufacturing the semiconductor package PK according to example embodiments may further include placing a third semiconductor chip on the opposite side of the surface on which the first semiconductor chip 10 and the second semiconductor chip 20 are attached on the interposer substrate 200.

FIG. 11 is a cross-sectional view illustrating the third semiconductor chip 50 arranged on the second substrate 200.

Referring to FIG. 11, the third semiconductor chip 50, which is an upper semiconductor chip, and an upper molding layer 70 surrounding or extending around the third semiconductor chip 50 may be placed on the second substrate 200. For example, the third semiconductor chip 50 is a memory device such as a high bandwidth memory (HBM) device, a dynamic random access memory (DRAM), and so on. The third semiconductor chip 50 may be electrically connected to the second upper connection pad 241 of the second substrate 200 through an upper portion connecting member 60.

As such, the method of manufacturing the semiconductor package PK according to example embodiments may have an interposer package on package (IPOP) structure in which an additional semiconductor chip 50 is placed on the second substrate 200.

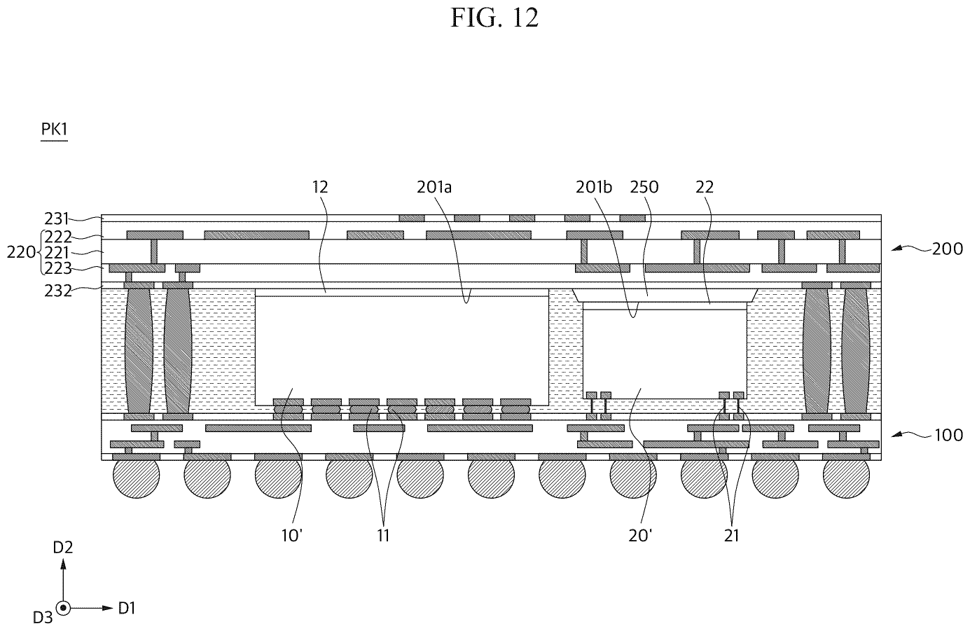

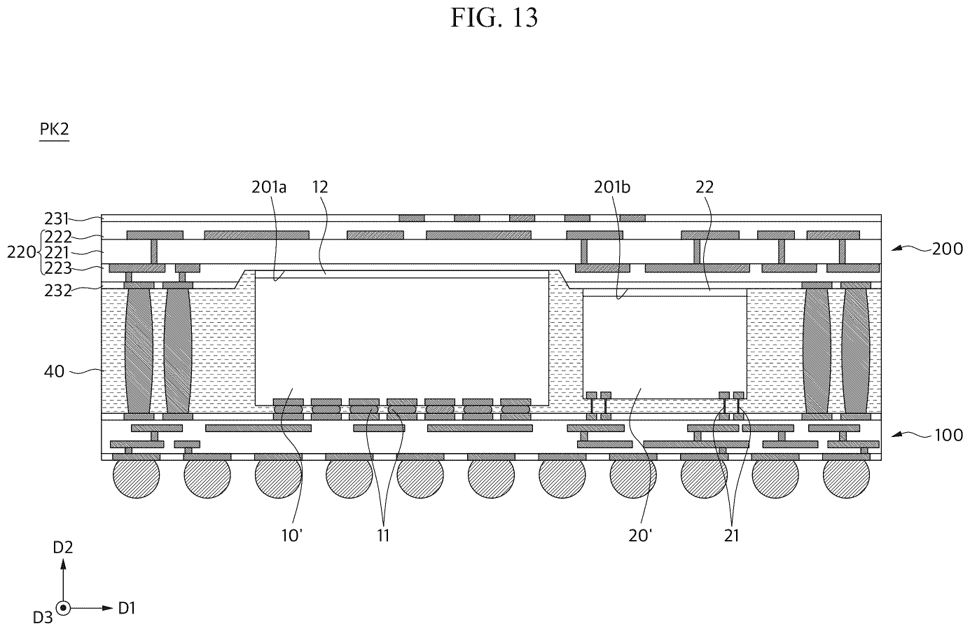

In another example embodiment, the interposer substrate 200 (in other words, the second substrate 200) of the semiconductor package PK may have a structure corresponding to multiple semiconductor chips having different heights. Hereinafter, semiconductor packages PK1 and PK2 according to other example embodiments will be described with reference to FIGS. 12 and 13.

FIG. 12 is a cross-sectional view of the semiconductor package PK1 according to an example embodiment.

In another example embodiment, a first semiconductor chip 10′ and a second semiconductor chip 20′ included in the semiconductor package PK1 may have different heights (or thicknesses). For example, referring to FIG. 12, the second semiconductor chip 20′ may be lower in height than the first semiconductor chip 10′ (e.g., the height of the second semiconductor chip 20′ in the second direction D2 is less than the height of the first semiconductor chip 10′ in the second direction D2).

In order to compensate for the height difference between the first semiconductor chip 10′ and the second semiconductor chip 20′, the lower surface 201 of the second substrate 200 and an upper surface of the second semiconductor chip 20′ may be provided with a protrusion 250 therebetween having a thickness that reduces the step difference between the lower surface of the first semiconductor chip 10′ and the lower surface of the second semiconductor chip 20′.

In another example embodiments, the second substrate 200 may include a first lower surface 201a and a second lower surface 201b that protrudes or extends further toward the first substrate 100 than the first lower surface 201a. The first semiconductor chip 10′ may be attached to the first lower surface 201a while the first adhesive member 12 is being interposed. The second semiconductor chip 20′ may be attached to the second lower surface 201b while the second adhesive member 22 is being interposed. Accordingly, despite the height difference between the first semiconductor chip 10′ and the second semiconductor chip 20′, the lower surface of the second semiconductor chip 20′ may be placed as close as possible to the first substrate 100, and thus the electrical performance may be improved with the shortened length of the conductive wire 21.

Meanwhile, with regard to all feature related to the semiconductor package PK1 explained through FIG. 12 except the height difference between the semiconductors (the first semiconductor chip 10′ and the second semiconductor chip 20′) and the protrusion 250, the features of the semiconductor package PK described with reference to FIGS. 1 to 11 may be applicable to the embodiment illustrated in FIG. 12.

FIG. 13 is a cross-sectional view of the semiconductor package PK2 according to an example embodiment.

In another example embodiment, a cavity structure may be formed on the lower surface 201 of the second substrate 200 to compensate for the height difference between the semiconductor chips (the first semiconductor chip 10′ and the second semiconductor chip 20′).

For example, referring to FIG. 13, a cavity structure that is more sunken or recessed than other parts may be formed on the lower surface of the second substrate 200, and the first semiconductor chip 10′ having a relatively tall height may be attached to the first lower surface 201a corresponding to the bottom surface of the cavity structure. The second semiconductor chip 20′ having a relatively short height may be attached to the second lower surface 201b outside of the cavity structure. By utilizing this type of cavity structure, the step difference between the lower surface of the first semiconductor chip 10′ and the lower surface of the second semiconductor chip 20′ may be reduced, and since the lower surface of the second semiconductor chip 20′ may be placed as close as possible to the first substrate 100, the length of the conductive wire 21 may be formed short. Thus, the electrical performance may increase.

Meanwhile, with regard to all features of the semiconductor package PK2 explained with reference to FIG. 13 except the height difference and cavity structure between semiconductor chips (the first semiconductor chip 10′ and the lower surface of the second semiconductor chip 20′), the features of the semiconductor package PK described through FIGS. 1 to 11 may be applicable to the embodiment illustrated in FIG. 13.

In the above, various embodiments of the present disclosure are described in detail. However, it will be apparent to those with knowledge in the technical field that scope of rights of this disclosure is not limited thereto, and various modifications and variations are possible without departing from the technical spirit of the present disclosure as set forth in the claims. Further, the above-described example embodiment may be implemented with some elements omitted, and each example embodiment may be implemented in combination with each other.

What is claimed is:

1. A semiconductor package comprising:
a first substrate comprising a first interconnection structure;
a first semiconductor chip on the first substrate;
a second semiconductor chip that is on the first substrate and spaced apart from the first semiconductor chip in a first direction that is parallel to an upper surface of the first substrate;
a second substrate that is spaced apart from the upper surface of the first substrate in a second direction that is perpendicular to the upper surface of the first substrate, wherein the second substrate contacts a first surface of the first semiconductor chip and a first surface of the second semiconductor chip;
a molding layer between the first substrate and the second substrate;
a plurality of conductive bumps that electrically connect the first interconnection structure to a first chip pad on a second surface of the first semiconductor chip that is opposite to the first surface of the first semiconductor chip; and
a plurality of conductive wires that electrically connect the first interconnection structure to a second chip pad on a second surface of the second semiconductor chip that is opposite to the first surface of the second semiconductor chip.

2. The semiconductor package of claim 1, wherein the plurality of conductive wires extend in the second direction.

3. The semiconductor package of claim 1, further comprising:
a first adhesive member between the first surface of the first semiconductor chip and the second substrate; and
a second adhesive member between the first surface of the second semiconductor chip and the second substrate.

4. The semiconductor package of claim 1, wherein the first substrate is a redistribution substrate comprising a redistribution layer and a plurality of first lower connection pads on a lower surface of the first substrate, and
the semiconductor package further comprises a plurality of external connection terminals bonded to the plurality of first lower connection pads.

5. The semiconductor package of claim 1, wherein the first substrate has thickness in the second direction that is less than a thickness in the second direction of the second substrate.

6. The semiconductor package of claim 1, wherein in the molding layer, a first portion between the plurality of conductive bumps and a second portion adjacent to the plurality of conductive wires comprise a same molding material.

7. The semiconductor package of claim 1, wherein the first surface of the first semiconductor chip is coplanar with the first surface of the second semiconductor chip.

8. The semiconductor package of claim 1, wherein the second substrate comprises:
a first lower surface that contacts the first surface of the first semiconductor chip; and
a second lower surface that extends further than the first lower surface in the second direction toward the first substrate,
wherein the first surface of the second semiconductor chip contacts the second lower surface.

9. The semiconductor package of claim 1, further comprising a plurality of conductive connectors that electrically connect the first substrate and the second substrate to each other,
wherein the first semiconductor chip and the second semiconductor chip are between the plurality of conductive connectors.

10. A method of manufacturing a semiconductor package comprising:
attaching a first surface of a first semiconductor chip and a first surface of a second semiconductor chip at different positions on a first surface of an interposer substrate;
attaching a connecting member to a second surface of the second semiconductor chip that is opposite to the first surface of the second semiconductor chip;
forming a molding layer on the first surface of the interposer substrate to at least partially overlap a second surface of the first semiconductor chip that is opposite to the first surface of the first semiconductor chip and the second surface of the second semiconductor chip;
forming a substantially flat molding surface by removing a portion of the molding layer; and
providing a base substrate on the substantially flat molding surface.

11. The method of manufacturing the semiconductor package of claim 10, further comprising forming a plurality of conductive connectors extending in a first direction perpendicular to the first surface of the interposer substrate,
wherein the first semiconductor chip and the second semiconductor chip are between the plurality of conductive connectors in a second direction parallel to the base substrate.

12. The method of manufacturing the semiconductor package of claim 10, wherein a plurality of conductive bumps are formed on the second surface of the first semiconductor chip, and
wherein the connecting member is a conductive wire extending in a direction perpendicular to the second surface of the second semiconductor chip.

13. The method of manufacturing the semiconductor package of claim 12, wherein forming the substantially flat molding surface comprises removing a portion of the plurality of conductive bumps, a portion of the conductive wire, and a portion of the molding layer.

14. The method of manufacturing the semiconductor package of claim 12, wherein the molding layer comprises a same molding material that extends around the plurality of conductive bumps and the conductive wire.

15. The method of manufacturing the semiconductor package of claim 10, wherein forming the base substrate comprises:
forming a metal pattern electrically connected to the first semiconductor chip and the second semiconductor chip;
providing a first insulation layer on at least a portion of the metal pattern; and
forming an external connection pad on a first surface of the first insulation layer that is opposite to a second surface of the first insulation layer facing the first semiconductor chip and the second semiconductor chip, wherein the external connection pad is electrically connected to the metal pattern.

16. The method of manufacturing the semiconductor package of claim 15, further comprising:
rotating the interposer substrate, the molding layer and the base substrate that are connected to each other; and
providing an external connection terminal on the external connection pad of the base substrate.

17. The method of manufacturing the semiconductor package of claim 16, further comprising providing a third semiconductor chip on a second surface of the interposer substrate,
wherein the second surface of the interposer substrate is opposite to the first surface of the interposer substrate.

18. A semiconductor package comprising:
a base substrate comprising a lower surface and an upper surface;
an external connection terminal on the lower surface of the base substrate;
a logic chip spaced apart from the base substrate in a first direction that is perpendicular to the upper surface of the base substrate;
a memory chip spaced apart from the base substrate in the first direction and from the logic chip in a second direction parallel to the upper surface of the base substrate;
an interposer substrate on an upper surface of the logic chip and an upper surface of the memory chip;
a molding layer between the base substrate and the interposer substrate;
a chip pad on a lower surface of the memory chip that is opposite to the upper surface of the memory chip;
an upper connection pad that is on the upper surface of the base substrate and faces the chip pad in the first direction; and
a connecting member comprising a first end that is electrically connected to the chip pad and a second end that is electrically connected to the upper connection pad.

19. The semiconductor package of claim 18, wherein the base substrate is a redistribution substrate comprising a redistribution layer,
wherein the interposer substrate is a printed circuit board, and
wherein the connecting member is a conductive wire extending in the first direction from the chip pad to the upper connection pad.

20. The semiconductor package of claim 18, further comprising an upper semiconductor chip on an upper surface of the interposer substrate opposite a lower surface thereof that is on the logic chip and the memory chip.
